(19) United States
(12) Patent Application Publication
(10) Pub. No.: US 2022/0153583 A1
(43) Pub. Date: May 19, 2022

(54) BULK BORON NITRIDE PARTICLES, THERMALLY CONDUCTIVE RESIN COMPOSITION, AND HEAT DISSIPATING MEMBER

(71) Applicant: DENKA COMPANY LIMITED, Tokyo (JP)

(72) Inventors: Go TAKEDA, Omuta-shi (JP); Takaaki TANAKA, Shibukawa-shi (JP)

(73) Assignee: DENKA COMPANY LIMITED, Tokyo (JP)

(21) Appl. No.: 17/441,263

(22) PCT Filed: Mar. 25, 2020
(86) PCT No.: PCT/JP2020/013386

§ 371 Date: Sep. 20, 2021

(30) Foreign Application Priority Data
Mar. 27, 2019 (JP) 2019-060324

(51) Int. Cl. C01B 21/064; C08K 3/38; C08L 63/00

(52) U.S. Cl. CPC C01B 21/0648; C08K 3/38; C01P 2004/50; C08K 2003/382; C08L 63/00

(57) ABSTRACT

The present invention relates to aggregated boron nitride particles including hexagonal boron nitride primary particles aggregated, including a spacer type coupling agent. The thermally conductive resin composition of the present invention includes the aggregated boron nitride particles of the present invention. The heat dissipation member of the present invention includes the thermally conductive resin composition of the present invention. According to the present invention, aggregated boron nitride particles that can suppress the formation of voids in a heat dissipation member produced by mixing with a resin, a thermally conductive resin composition including the aggregated boron nitride particles, and a heat dissipation member using the thermally conductive resin composition can be provided.

### TECHNICAL FIELD

The present invention relates to aggregated boron nitride particles, a thermally conductive resin composition including the same, and a heat dissipation member using the thermally conductive resin composition.

### BACKGROUND ART

A heat generating electronic device, such as a power device, a transistor, a thyristor, and a CPU, has an important issue how to dissipate efficiently the heat generated in use thereof. The heat dissipation measures having been generally performed include (1) high thermal conductivity is imparted to an insulating layer of a printed circuit board having the heat generating electronic device mounted thereon, and (2) the heat generating electronic device or a printed circuit board having the heat generating electronic device mounted thereon is attached to a heatsink via an electrically insulating thermal interface material. As the insulating layer of the printed circuit board and the thermal interface material, a silicone resin or an epoxy resin having ceramic powder filled therein is being used.

The heat generation density inside an electronic equipment is being increased over the years associated with the recent trend including the increase of the speed and the integration density of the circuit inside the heat generating electronic device and the increase of the mounting density of the heat generating electronic device on a printed circuit board. According to the trend, ceramic powder that has a higher thermal conductivity than ever is being demanded.

In view of the background, hexagonal boron nitride powder, which has excellent properties as an electric insulating material, such as high thermal conductivity, high insulating property, and low relative dielectric constant, is receiving attention.

However, hexagonal boron nitride particles have a thermal conductivity of 400 W/(m·K) in the in-plane direction (i.e., the a-axis direction) but a thermal conductivity of 2 W/(m·K) in the thickness direction (i.e., the c-axis direction), and thus has large anisotropy in thermal conductivity derived from the crystallographic structure and the scale-like form thereof. Furthermore, in the case where hexagonal boron nitride powder is filled in a resin, the particles thereof are oriented in the same direction. Therefore, the thickness directions (i.e., the c-axis directions) of the hexagonal boron nitride particles in the resin are arranged homogeneously in the same direction.

Accordingly, for example, in the production of a thermal interface material, the in-plane direction (i.e., the a-axis direction) of the hexagonal boron nitride particles becomes perpendicular to the thickness direction of the thermal interface material, and thereby the high thermal conductivity in the in-plane direction (i.e., the a-axis direction) of the hexagonal boron nitride particles has not been sufficiently used.

PTL 1 proposes a sheet having a high thermal conductivity having hexagonal boron nitride particles, the in-plane direction (i.e., the a-axis direction) of which are oriented in the thickness direction of the sheet, and thereby the high thermal conductivity in the in-plane direction (i.e., the a-axis direction) of the hexagonal boron nitride particles can be used.

However, there are issues including (1) a complicated production process due to the necessity of lamination of the oriented sheets in the subsequent process step, and (2) difficulty in securing the dimensional accuracy of the thickness of the sheet due to the necessity of cutting into a thin sheet form after the lamination and curing. Furthermore, the scale-like form of the hexagonal boron nitride particles increases the viscosity and deteriorates the fluidity in filling in a resin, preventing the particles from being filled in a high density.

For solving the issues, boron nitride powder having various forms with suppressed anisotropy in thermal conductivity of the hexagonal boron nitride particles has been proposed.

PTL 2 proposes the use of boron nitride powder including primary particles of hexagonal boron nitride particles that are aggregated without orientation in the same direction, and thereby the anisotropy in thermal conductivity is suppressed.

In addition, the known methods of producing aggregated boron nitride include spherical boron nitride produced by a spray-drying method (PTL 3), an aggregated material of boron nitride produced from boron carbide as a raw material (PTL 4), and aggregated boron nitride produced through repetition of pressing and pulverizing (PTL 5).

### CITATION LIST

### Patent Literatures

PTL 1: JP 2000-154265 A

PTL 2: JP 9-202663 A

PTL 3: JP 2014-40341 A

PTL 4: JP 2011-98882 A

PTL 5: JP 2007-502770 T

### SUMMARY OF INVENTION

### Technical Problem

However, the surface of the flat portion of the scale-like hexagonal boron nitride is significantly inactive, and therefore the surface of the boron nitride particles aggregated for suppressing the anisotropy in thermal conductivity is also significantly inactive. Accordingly, in the production of a heat dissipation member by mixing the aggregated boron nitride particles and a resin, there are cases where gaps are formed between the boron nitride particles and the resin, which become a factor of voids in the heat dissipation member. The voids formed in the heat dissipation member deteriorate the thermal conductivity of the heat dissipation member and deteriorate the insulation breakdown characteristics thereof.

Under the circumstances, an object of the present invention is to provide aggregated boron nitride particles that can suppress the formation of voids in a heat dissipation member produced by mixing with a resin, a thermally conductive resin composition including the aggregated boron nitride particles, and a heat dissipation member using the thermally conductive resin composition.

### Solution to Problem

The present inventors have made earnest studies for achieving the object, and can achieve the object by using aggregated boron nitride particles surface-treated with a spacer type coupling agent having an organic chain (spacer) between an organic functional group acting on an organic material and an inorganic functional group acting on an inorganic material.

The present invention is based on the aforementioned knowledge, and the substance thereof includes the following.

[1] Aggregated boron nitride particles including hexagonal boron nitride primary particles aggregated, including a spacer type coupling agent.

[2] The aggregated boron nitride particles according to the item [1], wherein the aggregated boron nitride particles have a content of the spacer type coupling agent of 0.1 to 1.5% by mass.

[3] The aggregated boron nitride particles according to the item [1] or [2], wherein the spacer type coupling agent has at least one kind of a reactive organic group selected from the group consisting of an epoxy group, an amino group, a vinyl group, and a (meth)acryl group, a silicon atom bonded to at least one alkoxy group, and an alkylene group having 1 to 14 carbon atoms disposed between the reactive organic group and the silicon atom.

[4] The aggregated boron nitride particles according to the item [3], wherein the reactive organic group of the spacer type coupling agent is a vinyl group.

[5] The aggregated boron nitride particles according to the item [3] or [4], wherein the alkylene group has 6 to 8 carbon atoms.

[6] The aggregated boron nitride particles according to any one of the items [3] to [5], wherein the silicon atom bonded to an alkoxy group is trimethoxysilane.

[7] A thermally conductive resin composition including the aggregated boron nitride particles according to any one of the items [1] to [6].

[8] A heat dissipation member including the thermally conductive resin composition according to the item [7].

### Advantageous Effects of Invention

According to the present invention, aggregated boron nitride particles that can suppress the formation of voids in a heat dissipation member produced by mixing with a resin, a thermally conductive resin composition including the aggregated boron nitride particles, and a heat dissipation member using the thermally conductive resin composition can be provided.

### BRIEF DESCRIPTION OF DRAWINGS

FIG. 1 shows the cross sectional observation photograph of the heat dissipation member of Example 1 by an electron microscope.

FIG. 2 shows the cross sectional observation photograph of the heat dissipation member of Comparative Example 1 by an electron microscope.

### DESCRIPTION OF EMBODIMENTS

### [Aggregated Boron Nitride Particles]

The present invention relates to aggregated boron nitride particles including hexagonal boron nitride primary particles aggregated, including a spacer type coupling agent. The aggregated boron nitride particles of the present invention will be described in detail below.

### (Specific Surface Area)

The specific surface area measured by the BET method of the aggregated boron nitride particles of the present invention is preferably 2 to 7 m²/g. In the case where the specific surface area measured by the BET method of the aggregated boron nitride particles is 2 m²/g or more, the contact area between the aggregated boron nitride particles and the resin can be increased, and voids can be prevented from being formed in the heat dissipation member. Furthermore, the aggregation form that exhibits the high thermal conductivity can be readily retained, and the insulation breakdown characteristics and the thermal conductivity of the heat dissipation member can be improved. In the case where the specific surface area measured by the BET method of the aggregated boron nitride particles is 7 m²/g or less, on the other hand, the aggregated boron nitride particles can be added to the resin in a high density, by which voids can be prevented from being formed in the heat dissipation member, and the insulation breakdown characteristics thereof can be improved. From the standpoint described above, the specific surface area measured by the BET method of the aggregated boron nitride particles is more preferably 2 to 6 m²/g, and further preferably 3 to 6 m²/g. The specific surface area measured by the BET method of the aggregated boron nitride particles may be measured by the method described in the section of Measurement Methods shown later.

### (Crushing Strength)

The crushing strength of the aggregated boron nitride particles of the present invention is preferably 5 MPa or more. In the case where the crushing strength of the aggregated boron nitride particles is 5 MPa or more, the aggregated boron nitride particles can be suppressed from being collapsed with the stress in mixing with a resin, pressing, or the like, and the decrease of the thermal conductivity due to the collapse of the aggregated boron nitride particles can be suppressed. From the standpoint described above, the crushing strength of the aggregated boron nitride particles is more preferably 6 MPa or more, and further preferably 7 MPa or more. The upper limit of the range of the crushing strength of the aggregated boron nitride particles is not particularly limited, and is, for example, 30 MPa. The crushing strength of the aggregated boron nitride particles may be measured by the method described in the section of Measurement Methods shown later.

### (Average Particle Diameter)

The average particle diameter of the aggregated boron nitride particles of the present invention is preferably 10 to 100 μm. In the case where the average particle diameter of the aggregated boron nitride particles is 10 μm or more, the long diameter of the hexagonal boron nitride primary particles constituting the aggregated boron nitride particles can be increased, and the thermal conductivity of the aggregated boron nitride particles can be increased. Furthermore, the insulation breakdown characteristics of the heat dissipation member can also be enhanced. In the case where the average particle diameter of the aggregated boron nitride particles is 100 μm or less, on the other hand, the heat dissipation member can be thinned. A thin heat dissipation member is demanded since the heat flow rate is proportional to the thermal conductivity and the thickness of the heat dissipation member. In the case where the average particle diameter of the aggregated boron nitride particles is 100 μm or less, furthermore, the heat dissipation member can be brought into sufficiently close contact with an object, from which heat is to be dissipated. In this case, the insulation breakdown characteristics of the heat dissipation member can also be enhanced. From the standpoint described above, the average particle diameter of the aggregated boron nitride particles is more preferably 15 to 90 μm, and further preferably 20 to 80 μm. The average particle diameter of the aggregated boron nitride particles may be measured by the method described in the section of Measurement Methods shown later.

### (Thermal Conductivity)

The aggregated boron nitride particles of the present invention can be favorably applied, for example, to a raw material of a heat dissipation member for a heat generating electronic device, such as a power device, and in particular, can be favorably used by filling in a resin composition for an insulating layer and a thermal interface material for a printed circuit board.

### (Ratio of Long Diameter to Thickness (Long Diameter/Thickness) of Hexagonal Boron Nitride Primary Particles)

In the aggregated boron nitride particles of the present invention, the ratio of the long diameter to the thickness (long diameter/thickness) of the hexagonal boron nitride primary particles is preferably 7 to 16. In the case where the ratio of the long diameter to the thickness (long diameter/thickness) of the hexagonal boron nitride primary particles is 7 to 16, the insulation breakdown characteristics of the heat dissipation member are further enhanced. From the standpoint described above, the ratio of the long diameter to the thickness (long diameter/thickness) of the hexagonal boron nitride primary particles is more preferably 8 to 15, and further preferably 8 to 13. The ratio of the long diameter to the thickness (long diameter/thickness) of the hexagonal boron nitride primary particles is a value obtained by dividing the average value of the long diameter of the hexagonal boron nitride primary particles by the average value of the thickness thereof. The average value of the long diameter and the average value of the thickness of the hexagonal boron nitride primary particles may be measured by the method described in the section of Measurement Methods shown later.

### (Long Diameter of Hexagonal Boron Nitride Primary Particles)

In the aggregated boron nitride particles of the present invention, the average value of the long diameter of the hexagonal boron nitride primary particles is preferably 2 to 12 μm. In the case where the average value of the long diameter of the hexagonal boron nitride primary particles is 2 μm or more, the thermal conductivity of the aggregated boron nitride particles can be improved. In the case where the average value of the long diameter of the hexagonal boron nitride primary particles is 2 μm or more, furthermore, the resin can readily penetrate to the aggregated boron nitride particles, and voids in the heat dissipation member can be suppressed from being formed. In the case where the average value of the long diameter of the hexagonal boron nitride primary particles is 12 μm or less, the aggregated boron nitride particles have a dense structure inside, by which the crushing strength of the aggregated boron nitride particles can be enhanced, and the thermal conductivity of the aggregated boron nitride particles can be improved. From the standpoint described above, the average value of the long diameter of the hexagonal boron nitride primary particles is more preferably 3 to 11 μm, and further preferably 3 to 10 μm.

### (Spacer Type Coupling Agent)

As described above, the aggregated boron nitride particles of the present invention include the spacer type coupling agent. According to the configuration, voids can be suppressed from being formed in a heat dissipation member produced by mixing the aggregated boron nitride particles and a resin.

The spacer type coupling agent means a coupling agent having an organic chain between an organic functional group acting on an organic material and an inorganic functional group acting on an inorganic material. In the following description, the organic chain may be referred to as a “spacer” in some cases. The organic chain may be an organic chain having 1 or more carbon atoms, and is preferably, for example, a linear alkylene group having 1 or more carbon atoms. Examples of the spacer type coupling agent include metal coupling agents containing Si, Ti, Zr, or Al in the form of a metal alkoxide, a metal chelate, or a metal halide, with no particular limitation, and the spacer type coupling agent is preferably selected corresponding to the resin used. Examples of the metal coupling agent preferred as the spacer type coupling agent include a silane coupling agent, a titanium coupling agent, a zirconium coupling agent, and an aluminum coupling agent. One kind of the metal coupling agent may be used alone, or two or more kinds thereof may be used in combination. Among the metal coupling agents, a silane coupling agent is more preferred from the standpoint of the capability of suppressing the formation of voids in the heat dissipation member.

The silane coupling agent is a compound that has an organic functional group acting on an organic material and a hydrolyzable silyl group acting on an inorganic material, and can be represented by the following general formula (1):

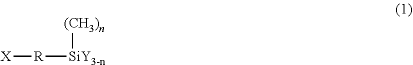

wherein X represents a reactive organic group, Y represents a hydrolyzable group, R represents an organic chain, and n represents an integer of 0 to 2. The compound that has the organic chain (R) is the spacer type silane coupling agent.

Examples of the reactive organic group (X) include an epoxy group, an amino group, a vinyl group, a (meth)acryl group, and a mercapto group. Examples of the hydrolyzable group (Y) include an acetoxy group, an oxime group, an alkoxy group, an amide group, and an isopropenyloxy group. The organic chain (R) is, for example, an alkylene group having 1 or more carbon atoms, and preferably an alkylene group having 1 to 14 carbon atoms.

In the silane coupling agent as the spacer type silane coupling agent, from the standpoint of the capability of suppressing the formation of voids in the heat dissipation member, a silane coupling agent having a reactive organic group, a silicon atom bonded to at least one alkoxy group, and an alkylene group having 1 to 14 carbon atoms disposed between the reactive organic group and the silicon atom is more preferred.

From the same standpoint as above, the reactive organic group of the silane coupling agent is preferably at least one kind of a reactive organic group selected from the group consisting of an epoxy group, an amino group, a vinyl group, and a (meth)acryl group, and more preferably a vinyl group.

From the standpoint of the improvement of the insulation breakdown characteristics, the number of carbon atoms of the alkylene group disposed between the reactive organic group and the silicon atom is preferably 2 to 12, more preferably 3 to 11, further preferably 4 to 10, still further preferably 5 to 9, and particularly preferably 6 to 8. The alkylene group disposed between the reactive organic group and the silicon atom is preferably linear.

From the same standpoint as above, the silicon atom bonded to at least one alkoxy group is preferably a silicon atom bonded to at least two alkoxy groups, and preferably a silicon atom bonded to three alkoxy groups. The alkoxy group is preferably a methoxy group or an ethoxy group, and more preferably a methoxy group.

Specific examples of the spacer type silane coupling agent include a vinyl based silane coupling agent, such as propenyltrimethoxysilane, propenyltriethoxysilane, propenylmethyldimethoxysilane, propenylmethyldethoxysilane, butenyltrimethoxysilane, butenyltriethoxysilane, butenylmethyldimethoxysilane, butenylmethyldiethoxysilane, pentenyltrimethoxysilane, pentenyltriethoxysilane, pentenylmethyldiethoxysilane, pentenylmethyldiethoxysilane, hexenyltrimethoxysilane, hexenyltriethoxysilane, hexenylmethyldimethoxysilane, hexenylmethyldiethoxysilane, heptenyltrimethoxysilane, heptenyltriethoxysilane, heptenylmethyldimethoxysilane, heptenylmethyldiethoxysilane, octenyltrimethoxysilane, octenyltriethoxysilane, octenylmethyldimethoxysilane, octenylmethyldiethoxysilane, nonenyltrimethyoxysilane, nonenyltriethoxysilane, nonenylmethyldimethoxysilane, nonenylmethyldiethoxysilane, decenyltrimethoxysilane, decenyltriethoxysilane, decenylmethyldimethoxysilane, decenylmethyldiethoxysilane, undecenyltrimethoxysilane, undecenyltriethoxysilane, undecenylmethyldimethoxysilane, undecenylmethyldiethoxysilane, dodecenyltrimethoxysilane, dodecenyltriethoxysilane, dodecenylmethyldimethoxysilane, and dodecenylmethyldiethoxysilane; an epoxy based silane coupling agent, such as 3-glycidoxypropylmethylthmethoxysilane, 3-glycidoxypropyltrimethoxysilane, 3-glycidoxypropylmethyldiethoxysilane, 3-glycidoxypropyltriethoxysilane, and 8-glycidoxyoctyltrimethoxysilane; an amino based silane coupling agent, such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysilane, 3-triethoxysilyl-N-(1,3-dimethylbutyliden)propylamine, N-phenyl-3-aminopropyltrimethoxysilane, and N-2-(aminoethyl)-8-aminooctyltrimethoxysilane; and a (meth)acryl based silane coupling agent, such as 3-acryloxypropyltrimethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, and 8-methacryloxyoctyltrimethoxysilane. One kind of the spacer type coupling agent may be used alone, or two or more kinds thereof may be used in combination. Among these, a vinyl based silane coupling agent is preferred from the standpoint of the capability of suppressing the formation of voids in the heat dissipation member. In the vinyl based silane coupling agent, from the standpoint of the improvement of the insulation breakdown characteristics of the heat dissipation member, a vinyl based silane coupling agent having a long organic chain is preferred, and specifically, octenyltrimethoxysilane, octenyltriethoxysilane, octenylmethyldimethoxysilane, octenylmethyldiethoxysilane, nonenyltrimethyoxysilane, nonenyltriethoxysilane, nonenylmethyldimethoxysilane, nonenylmethyldiethoxysilane, decenyltrimethoxysilane, decenyltriethoxysilane, decenylmethyldimethoxysilane, and decenylmethyldiethoxysilane are more preferred, octenyltrimethoxysilane, octenyltriethoxysilane, octenylmethyldimethoxysilane, and octenylmethyldiethoxysilane are further preferred, and octenyltrimethoxysilane is particularly preferred.

The content of the spacer type coupling agent in the aggregated boron nitride particles is preferably 0.1 to 1.5% by mass. In the case where the content of the spacer type coupling agent is 0.1% by mass or more, the spacer type coupling agent can exert a sufficient effect on the suppression of the formation of voids in the heat dissipation member. In the case where the content of the spacer type coupling agent is 1.5% by mass or less, on the other hand, the decrease of the thermal conductivity of the heat dissipation member due to the increase of the content of the spacer type coupling agent can be suppressed. From the standpoint described above, the content of the spacer type coupling agent in the aggregated boron nitride particles is more preferably 0.2 to 1.2% by mass, and further preferably 0.3 to 1.0% by mass.

### (Production Method of Aggregated Boron Nitride Particles)

The aggregated boron nitride particles of the present invention can be produced by a production method of aggregated boron nitride particles, including a pressure nitridation firing step, a decarbonization crystallization step, and a surface treatment step. The steps each will be described in detail below.

### <Pressure Nitridation Firing Step>

In the pressure nitridation firing step, boron carbide having an average particle diameter of 6 μm or more and 55 μm or less and a carbon amount of 18% or more and 21% or less is subjected to pressure nitridation firing. According to the procedure, boron carbonitride that is favorable as a raw material of the aggregated boron nitride particles of the present invention can be obtained.

### Boron Carbide as Raw Material Used in Pressure Nitridation Step

Since the particle diameter of the boron carbide as the raw material used in the pressure nitridation step strongly influences the aggregated boron nitride particles finally obtained, it is necessary to select boron carbide having a suitable particle diameter, and boron carbide having an average particle diameter of 6 to 55 μm is preferably used as the raw material. At this time, the amounts of boric acid and free carbon as impurities are preferably small.

The average particle diameter of the boron carbide as the raw material is preferably 6 μm or more, more preferably 7 μm or more, and further preferably 10 μm or more, and is preferably 55 μm or less, more preferably 50 μm or less, and further preferably 45 μm or less. The average particle diameter of the boron carbide as the raw material is preferably 7 to 50 μm, and more preferably 7 to 45 μm. The average particle diameter of the boron carbide can be measured in the similar manner as for the aggregated boron nitride particles.

The carbon amount of the boron carbide as the raw material used in the pressure nitridation step is preferably lower than the composition of B₄C (21.7%), and boron carbide having a carbon amount of 18 to 21% is preferably used. The carbon amount of the boron carbide is preferably 18% or more, and more preferably 19% or more, and is preferably 21% or less, and more preferably 20.5% or less. The carbon amount of the boron carbide is preferably 18% to 20.5%. The carbon amount of the boron carbide is to be regulated to the range since the dense aggregated boron nitride particles can be formed with a less amount of carbon discharged in the decarbonization crystallization step described later, and also since the carbon amount of the aggregated boron nitride particles finally produced is reduced. It is difficult to produce stable boron carbide having a carbon amount of less than 18% due to the too large deviation from the theoretical composition.

As a method for producing the boron carbide as the raw material, boric acid and acetylene black may be mixed and then heated at 1,800 to 2,400° C. for 1 to 10 hours in an atmosphere, and thus bulk boron carbide can be obtained. The bulk raw material obtained may be pulverized and then sieved, and appropriately subjected to washing, removal of impurities, drying, and the like, and thus boron carbide powder can be obtained. In mixing boric acid and acetylene black as raw materials of the boron carbide, the amount of acetylene black is preferably 25 to 40 parts by mass per 100 parts by mass of boric acid.

The atmosphere for the production of boron carbide is preferably an inert gas, and examples of the inert gas include argon gas and nitrogen gas, which may be appropriately used alone or as a combination thereof. In these, argon gas is preferred.

The bulk boron nitride may be pulverized by using a common pulverizing or cracking machine, and may be pulverized, for example, for 0.5 to 3 hours. The boron carbide after the pulverization is preferably sieved to a particle diameter of 75 μm or less with a sieve net.

### Pressure Nitridation Firing

The pressure nitridation firing is performed in an atmosphere having a particular firing temperature and a particular pressure condition.

The firing temperature in the pressure nitridation firing is preferably 1,700° C. or more, and more preferably 1,800° C. or more, and is preferably 2,400° C. or less, and more preferably 2,200° C. or less. The firing temperature in the pressure nitridation firing is preferably 1,800 to 2,200° C.

The pressure in the pressure nitridation firing is preferably 0.6 MPa or more, and more preferably 0.7 MPa or more, and is preferably 1.0 MPa or less, and more preferably 0.9 MPa or less. The pressure in the pressure nitridation firing is preferably 0.7 to 1.0 MPa.

The combination of the firing temperature and the pressure condition in the pressure nitridation firing is preferably a firing temperature of 1,800° C. or more and a pressure of 0.7 to 1.0 MPa. With a firing temperature of 1,800° C. and a pressure of 0.7 MPa or more, the nitridation of boron carbide can be sufficiently performed. The production is industrially preferably performed under a pressure of 1.0 MPa or less.

A gas that can proceed nitridation reaction is demanded for the atmosphere for the pressure nitridation firing, and examples thereof include nitrogen gas and ammonia gas, which may be used alone or as a combination of two or more kinds thereof. In these, nitrogen gas is preferred from the standpoint of the nitridation and the cost. The atmosphere preferably contains nitrogen gas in an amount of 95% (v/v) or more, and more preferably 99.9% or more.

The firing time in the pressure nitridation firing is preferably 6 to 30 hours, and more preferably 8 to 20 hours.

### <Decarbonization Crystallization Step>

In the decarbonization crystallization step, the boron carbonitride obtained in the pressure nitridation step is subjected to a heat treatment in (a) an atmosphere of ordinary pressure or more, at (b) a particular temperature rise rate, (c) heating to a firing temperature in a particular temperature range, and (d) retaining the firing temperature for a certain period of time. According to the procedure, the aggregated boron nitride particles including primary particles (i.e., scale-like hexagonal boron nitride as primary particles) aggregated into clumps can be obtained.

In the decarbonization crystallization step, the boron carbonitride obtained from the boron carbide thus prepared above is decarbonized, and is simultaneously made into a scale form having the prescribed size and aggregated to the aggregated boron nitride particles.

The decarbonization crystallization step is preferably a heat treatment performed in an atmosphere of ordinary pressure or more by heating to a temperature where the decarbonization can be started, then heating to a firing temperature of 1,750° C. or more at a temperature rise rate of 5° C./min or less, and retaining at the firing temperature for more than 0.5 hour to less than 40 hours. The decarbonization crystallization step is more preferably a heat treatment performed in an atmosphere of ordinary pressure or more by heating to a temperature where the decarbonization can be started, then heating to a firing temperature of 1,800° C. or more at a temperature rise rate of 5° C./min or less, and retaining at the firing temperature for 1 to 30 hours.

In the decarbonization crystallization step, it is preferred that the boron carbonitride obtained in the pressure nitridation firing step and at least one compound of boron oxide and boric acid (and other raw materials depending on necessity) are mixed to produce a mixture, and the resulting mixture is subjected to decarbonization crystallization. The mixing ratio of the boron carbonitride and the at least one compound of boron oxide and boric acid is preferably 10 to 300 parts by mass of the at least one compound of boron oxide and boric acid, and more preferably 15 to 250 parts by mass of the at least one compound of boron oxide and boric acid, per 100 parts by mass of the boron carbonitride. For boron oxide, the mixing ratio converted to boric acid is used.

In the decarbonization crystallization step, the pressure condition of “(a) the atmosphere of ordinary pressure or more” is preferably ordinary pressure or more, more preferably 0.1 MPa or more, and further preferably 0.2 MPa or more. The upper limit of the pressure condition of the atmosphere is not particularly limited, and is preferably 1 MPa or less, and more preferably 0.5 MPa. The pressure condition of the atmosphere is preferably 0.2 to 0.4 MPa.

In the decarbonization crystallization step, the “atmosphere” is preferably nitrogen gas, and is preferably 90% (v/v) of nitrogen gas in the atmosphere, and more preferably high purity nitrogen gas (99.9% or more).

In the decarbonization crystallization step, the heating at “(b) the particular temperature rise rate” may be performed in single stage or in multiple stages. Multiple stages are preferably selected for shortening the period of time for heating to the temperature where the decarbonization can be started. The “first stage heating” in the multiple stages is preferably heating to the “temperature where the decarbonization can be started”. The “temperature where the decarbonization can be started” is not particularly limited and may be a temperature having been ordinarily used, and for example, the temperature may be approximately 800 to 1,200° C. (preferably approximately 1,000° C.). The “first stage heating” may be performed, for example, in a range of 5 to 20° C./min, and preferably 8 to 12° C./min.

After the first stage heating, the second stage heating is preferably performed. The “second stage heating” is more preferably performed as the “(c) heating to a firing temperature in a particular temperature range” in the decarbonization crystallization step.

The upper limit of the “second stage heating” is preferably 5° C./min or less, more preferably 4° C./min or less, further preferably 3° C./min or less, and still further preferably 2° C./min or less. A lower temperature rise rate is preferred since the particle growth can be readily homogeneous.

The “second stage heating” is preferably 0.1° C./min or more, more preferably 0.5° C./min or more, and further preferably 1° C./min or more. The case where the “second stage heating” that is 1° C. or more is preferred from the standpoint of cost since the production time can be reduced. The “second stage heating” is preferably 0.1 to 5° C./min. In the case where the temperature rise rate in the “second stage heating” exceeds 5° C./min, the particle growth may occur heterogeneously to fail to provide a homogeneous structure, resulting in a possibility that the crushing strength of the aggregated boron nitride particles is lowered.

In the “(c) heating to a firing temperature in a particular temperature range”, the particular temperature range (i.e., the firing temperature after heating) is preferably 1,750° C. or more, more preferably 1,800° C. or more, and further preferably 2,000° C. or more, and is preferably 2,200° C. or less, and more preferably 2,100° C. or less.

In the case where the firing temperature after heating is less than 1,750° C., the particle growth may not sufficiently occur, resulting in a concern that the thermal conductivity is lowered. In the case where the firing temperature is 1,800° C. or more, the particle growth may readily occur favorably, and the thermal conductivity can be readily enhanced.

In the “(d) retaining the firing temperature for a certain period of time”, the certain period of time (i.e., the firing time after heating) is preferably more than 0.5 hour and less than 40 hours. The “firing time” is more preferably 1 hour or more, further preferably 3 hours or more, still further preferably 5 hours or more, and still more further preferably 10 hours or more, and is more preferably 30 hours or less, and further preferably 20 hours or less. In the case where the firing time after heating exceeds 0.5 hour, the particle growth occurs favorably, and in the case where the firing time after heating is less than 40 hours, excessive particle growth deteriorating the particle strength can be suppressed, and the industrial disadvantage due to the long firing time can be reduced.

The aggregated boron nitride particles of the present invention can be obtained through the pressure nitridation firing step and the decarbonization crystallization step described above. Furthermore, in the case where the weak agglomeration among the aggregated boron nitride particles is to be relieved, the aggregated boron nitride particles obtained through the decarbonization crystallization step are preferably pulverized or cracked, and then classified. The pulverization and cracking are not particularly limited, and may be performed by using a common pulverizing or cracking machine, and the classification may be performed by a common sieving method providing an average particle diameter of 15 to 90 μm. Examples thereof include a method of pulverizing with a Henschel mixer or a mortar, and then classifying with a vibration sieving machine.

### <Surface Treatment Step>

In the surface treatment step, the aggregated boron nitride particles obtained in the decarbonization crystallization step is surface-treated by using the spacer type silane coupling agent. The surface treatment with the spacer type coupling agent may be performed by dry-mixing the aggregated boron nitride particles and the spacer type coupling agent, or may be performed by adding a solvent to the aggregated boron nitride particles and the spacer type coupling agent, and wet-mixing them. The spacer type silane coupling agent used in the surface treatment step is the same as the spacer type silane coupling agent included in the aggregated boron nitride particles described above.

The treated amount of the spacer type coupling agent added is preferably such an amount that in terms of values by X-ray photoelectron spectroscopy, 0.1% by atom or more and 3.0% by atom or less of any of Si, Ti, Zr, and Al exists in the composition of the 10 nm surface of the aggregated boron nitride particles. In the case where the amount is 0.1% by atom or more, the effect on the formation of voids in the heat dissipation member can be sufficiently exerted, and in the case where the amount is 3.0% by atom or less, the decrease of the thermal conductivity of the heat dissipation member due to the spacer type coupling agent included can be suppressed. The kind of the spacer type coupling agent can be detected from plural fragment peaks derived from the coupling agent from the result of mass analysis of time-of-flight secondary ion mass spectrometry TOF-SIMS or the like.

In the surface treatment, the temperature in the coupling reaction condition is preferably 10 to 70° C., and more preferably 20 to 70° C. In the surface treatment, the period of time in the coupling reaction condition is preferably 0.2 to 5 hours, and more preferably 0.5 to 3 hours. The amount of the spacer type coupling agent used is not particularly limited, as far as the content of the spacer type coupling agent is 0.1 to 1.5% by mass, and is preferably 0.1 to 5 parts by mass, and more preferably 0.1 to 3 parts by mass, per 100 parts by mass of the aggregated boron nitride particles.

The features of the aggregated boron nitride particles obtained by the production method of aggregated boron nitride particles described above have been described in the section of the aggregated boron nitride particles.

### [Thermally Conductive Resin Composition]

The thermally conductive resin composition of the present invention includes the aggregated boron nitride particles of the present invention. The thermally conductive resin composition can be produced by a known production method. The resulting thermally conductive resin composition can be widely applied to thermal grease, heat dissipation members, and the like.

### (Resin)

Examples of the resin used in the thermally conductive resin composition of the present invention include an epoxy resin, a silicone resin, silicone rubber, an acrylic resin, a phenol resin, a melamine resin, a urea resin, an unsaturated polyester, a fluorine resin, a polyamide (such as polyimide, polyamideimide, and polyetherimide), a polyester (such as polybutylene terephthalate and polyethylene terephthalate), a polyphenylene ether, a polyphenylene sulfide, a wholly aromatic polyester, a polysulfone, a liquid crystal polymer, a polyether sulfone, a polycarbonate, a maleimide-modified resin, an ABS resin, an AAS (acrylonitrile-acrylic rubber-styrene) resin, an AES (acrylonitrile-ethylene-propylene-diene rubber-styrene) resin. An epoxy resin (preferably a naphthalene type epoxy resin) is preferred particularly as an insulating layer of a printed circuit board due to the excellent properties thereof including the heat resistance and the adhesion strength to a copper foil circuit. A silicone resin is preferred particularly as a thermal interface material due to the excellent property thereof including the heat resistance, the flexibility, and the adhesiveness to a heatsink or the like.

The content of the aggregated boron nitride particles in 100% by volume of the thermally conductive resin composition is preferably 30 to 85% by volume, and more preferably 40 to 80% by volume. In the case where the amount of the aggregated boron nitride particles is 30% by volume or more, the thermal conductivity can be enhanced, and a sufficient heat dissipation capability can be readily obtained. In the case where the amount of the aggregated boron nitride particles is 85% by volume or less, the tendency of the formation of voids in molding can be reduced, and the deterioration of the insulating property and the mechanical strength can be reduced.

The thermally conductive resin composition may include additional components other than the aggregated boron nitride particles and the resin. The additional components include an additive, an impurity, and the like, and the amount thereof may be 5% by volume or less, 3% by volume or less, or 1% by volume or less.

### [Heat Dissipation Member]

The heat dissipation member of the present invention includes the thermally conductive resin composition of the present invention. The heat dissipation member of the present invention is not particularly limited, as far as the member is used for a heat dissipation measure. Examples of the heat dissipation member of the present invention include a printed circuit board having a heat generating electronic device, such as a power device, a transistor, a thyristor, and a CPU, mounted thereon, the heat generating electronic device, and an electrically insulating thermal interface material used for attaching the heat generating electronic device or the printed circuit board having the heat generating electronic device mounted thereon to a heatsink. The heat dissipation member can be produced, for example, in such a manner that the thermally conductive resin composition is molded to produce a molded article, the molded article thus produced is spontaneously dried, the molded article thus spontaneously dried is pressed, the molded article thus pressed is heat dried, and the molded article thus heat dried is worked.

### [Measurement Methods]

The measurement methods are as follows.

### (1) Specific Surface Area

The specific surface area of the aggregated boron nitride particles is measured by the BET one point method with a specific surface area measuring equipment (Quantasorb, produced by Yuasa-Ionics Co., Ltd.). In the measurement, 1 g of a specimen is dried and deaerated at 300° C. for 15 minutes, and then measured.

### (2) Crushing Strength

The crushing strength is measured according to JIS R1639-5. The measurement equipment used is a micro compression testing machine (“MCT-W500”, produced by Shimadzu Corporation). The particle strength (σ: MPa) is obtained in such a manner that 20 or more particles are measured according to the expression σ=α×P/(π×d²) from the dimensionless number (α=2.48) varying depending on the position within the particle, the crushing test force (P: N), and the particle diameter (d: μm), and the value at an accumulated crushing rate of 63.2% is calculated.

### (3) Evaluation Method of Primary Particle Diameter

For the aggregated boron nitride particles thus produced, particles having a long diameter and a short diameter that can be confirmed in the surface state are observed with a scanning electron microscope (for example, “JSM-60 IOLA” (produced by JEOL, Ltd.) at an observation magnification of 1,000 to 5,000. The resulting particle images are incorporated to an image analysis software, such as “Mac-view”, and measured for the long diameters and the thicknesses of the incorporated particles, and the average values of the long diameters and the thicknesses of arbitrary 100 particles are calculated and designated as the average value of the long diameter and the average value of the thickness respectively.

### (4) Average Particle Diameter

The average particle diameter is measured with a laser diffraction scattering particle size distribution analyzer (LS-13 320), produced by Beckman Coulter Inc. The average particle diameter of the specimen that is not subjected to a homogenizer before the measurement treatment is designated as the average particle diameter. The resulting average particle diameter is an average particle diameter by the volume statistics value.

### (5) Measurement of Carbon Amount

The carbon amount is measured with a carbon/sulfur simultaneous analyzer “CS-444LS” (produced by LECO Corporation).

### EXAMPLES

The present invention will be described in detail with reference to examples and comparative examples below. The present invention is not limited to the examples.

Heat dissipation members of the examples and the comparative examples were evaluated as follows.

### (Insulation Breakdown Strength)

The insulation breakdown strength of the heat dissipation member were measured according to JIS C2110.

Specifically, the heat dissipation member in a sheet form was worked into a size of 10 cm×10 cm, a circular copper layer having a diameter of 25 mm was formed on one surface of the worked heat dissipation member, and a copper layer was formed on the entire of the other surface thereof so as to produce a test specimen.

Electrodes were disposed to hold the test specimen, and an alternating voltage was applied to the test specimen in an electric insulating oil (trade name: FC-3283, produced by 3M Japan, Ltd.). The voltage applied to the test specimen was increased from 0 V at a rate (500 V/s) that caused insulation breakdown after 10 to 20 seconds in average from the start of application of voltage. The voltage V₁₅ (kV) at the insulation breakdown occurring 15 times per one test specimen was measured. The voltage V₁₅ (kV) was divided by the thickness (mm) of the test specimen, so as to calculate the insulation breakdown strength (kV/mm). An insulation breakdown strength of 41 (kV/mm) or more is favorable, that of 45 (kV/mm) or more is more favorable, and that of 50 (kV/mm) or more is further favorable.

### (Relative Thermal Conductivity)

The thermal conductivity of the heat dissipation member was measured according to ASTM D5470.

The heat dissipation member was held with two copper fixtures under a load of 100 N. Grease (trade name: G-747, produced by Shin-Etsu Chemical Co., Ltd.) was applied between the heat dissipation member and the copper fixture. The upper copper fixture was heated with a heater, and the temperature (T_{U}) of the upper copper fixture and the temperature (T_{B}) of the bottom copper fixture were measured. The thermal conductivity (H) was calculated according to the following expression (1).

H=t/((T_{U}−T_{B})/Q×S) (1)

In the expression, t represents the thickness (m) of the heat dissipation member, Q represents the heat flow rate (W) calculated from the electric power of the heater, and S represents the area (m²) of the heat dissipation member.

The thermal conductivity was measured for three specimens, and the average value of the thermal conductivity of the three specimens was designated as the thermal conductivity of the heat dissipation member. The thermal conductivity of the heat dissipation member was divided by the thermal conductivity of the heat dissipation member of Comparative Example 1, so as to calculate the relative thermal conductivity.

### (Evaluation of Voids)

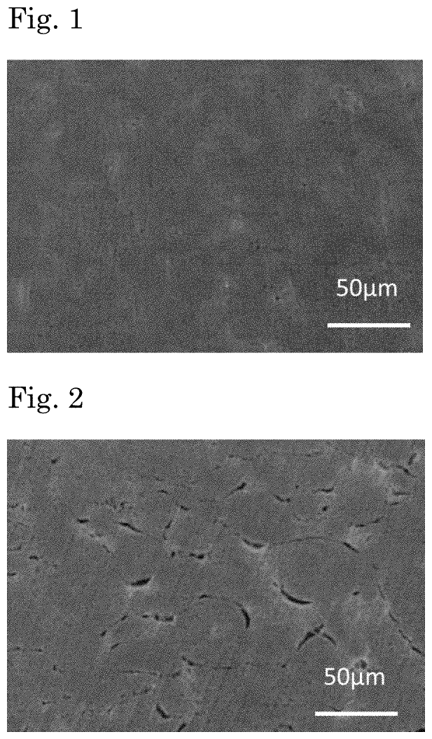

The heat dissipation member was worked with a diamond cutter to provide a cross section, which was then processed by the CP (cross section polisher) method, and after fixing to a specimen stage, subjected to osmium coating. The cross section of the heat dissipation member was observed with a scanning electron microscope (for example, “JSM-6010LA” (produced by JEOL, Ltd.) at a magnification of 500 for 10 view fields, and voids of the heat dissipation member were investigated. In the observation of 10 view fields in the vicinity of the surface of the sheet at a magnification of 500, the case where 5 or more voids having a length of 5 μm or more in terms of average per one view field were not observed was evaluated as “none”, and the case where the voids were observed was evaluated as “found”. As examples of the cross sectional observation photograph, FIG. 1 shows the cross sectional observation photograph of the heat dissipation member of Example 1 by an electron microscope, and FIG. 2 shows the cross sectional observation photograph of the heat dissipation member of Comparative Example 1 by an electron microscope.

### Example 1

In Example 1, aggregated boron nitride particles were synthesized through the boron carbide synthesis, the pressure nitridation step, the decarbonization crystallization step, and the surface treatment step in the following manner, and filled in a resin.

### (Boron Carbide Synthesis)

100 parts by mass of orthoboric acid (hereinafter referred to as boric acid), produced by Nippon Denko Co., Ltd., and 35 parts by mass of acetylene black (HS100), produced by Denka Co., Ltd., were mixed with a Henschel mixer, then charged in a graphite crucible, and heated in an arc furnace in an argon atmosphere at 2,200° C. for 5 hours, so as to synthesize boron carbide (B₄C). The bulk boron carbide thus synthesized was pulverized with a ball mill for 1 hour, sieved to a particle diameter of 75 μm or less with a sieve net, and further washed with a nitric acid aqueous solution to remove impurities, such as an iron content, followed by filtering and drying, so as to produce boron carbide powder having an average particle diameter of 20 μm. The carbon amount of the resulting boron carbide powder was 20.0%.

### (Pressure Nitridation Step)

The boron carbide thus synthesized was charged in a boron nitride crucible, and heated in a resistance heating furnace in a nitrogen atmosphere under condition of 2,000° C. and 9 atm (0.8 MPa) for 10 hours, so as to provide boron carbonitride (B₄CN₄).

(Decarbonization Crystallization Step) 100 parts by mass of the boron carbonitride thus synthesized and 90 parts by mass of boric acid were mixed with a Henschel mixer, then charged in a boron nitride crucible, and heated in a resistance heating furnace under a pressure condition of 0.2 MPa in a nitrogen atmosphere at a temperature rise rate from room temperature to 1,000° C. of 10° C./min and a temperature rise rate at 1,000° C. or more of 2° C./min to a firing temperature of 2,020° C. for a retention time of 10 hours, so as to synthesize aggregated boron nitride particles including primary particles aggregated into clumps. The aggregated boron nitride particles thus synthesized were cracked with a mortar for 10 minutes, and then classified with a nylon sieve having a mesh of 75 μm as a sieve net. The fired material was cracked and classified to provide aggregated boron nitride particles including primary particles aggregated into clumps.

The specific surface area measured by the BET method of the resulting aggregated boron nitride particles was 4 m²/g, and the crashing strength thereof was 9 MPa. The ratio of the long diameter to the thickness (long diameter/thickness) of the hexagonal boron nitride primary particles of the resulting aggregated boron nitride particles was 11. The average particle diameter of the resulting aggregated boron nitride particles was 35 μm, and the carbon amount thereof was 0.06%.

### (Surface Treatment Step)

1 part by mass of a silane coupling agent (trade name: KBM-1083, produced by Shin-Etsu Chemical Co., Ltd., 7-octenyltrimethoxysilane) was added to 100 parts by mass of the aggregated boron nitride particles, and the mixture was dry-mixed for 0.5 hour and sieved with a sieve of 75 μm, so as to provide surface-treated aggregated boron nitride particles. 7-Octenyltrimethoxysilane has a vinyl group as the reactive organic group and an alkylene group having 6 carbon atoms as the organic chain connecting the reactive organic group and the Si atom.

### (Production of Heat Dissipation Member)

50% by volume of the resulting surface-treated aggregated boron nitride particles and 50% by volume of a silicone resin (trade name: CF-3110, produced by Toray Dow Corning Silicone Co., Ltd.), based on 100% by volume in total of the aggregated boron nitride particles and the silicone resin, 1 part by mass of a crosslinking agent (trade name: Kayahexa AD, produced by Kayak Akzo Corporation) per 100 parts by mass of the silicone resin, and toluene as a viscosity modifier weighed to make a solid concentration of 60% by weight were placed in an agitator (trade name: Three-One Motor, produced by HEIDON) and mixed with a turbine agitation blade for 15 hours, so as to produce a thermally conductive resin composition.

The thermally conductive resin composition thus produced was coated on one surface of a glass cloth (trade name: H25, produced by Unitika, Ltd.) to a thickness of 0.2 mm with a comma coater, and dried at 75° C. for 5 minutes. Thereafter, the thermally conductive resin composition was coated on the other surface of the glass cloth to a thickness of 0.2 mm with the comma coater and dried at 75° C. for 5 minutes, so as to produce a laminate.

The laminate was subjected to thermal press under condition of a temperature of 150° C. and a pressure of 150 kgf/cm² for 45 minutes with a plate press machine (produced by Yanase Seisakusho Co., Ltd.), so as to produce a heat dissipation member in a sheet form having a thickness of 0.3 mm. The heat dissipation member was further subjected to secondary heating at 150° C. for 4 hours at a normal pressure, so as to produce a heat dissipation member of Example 1.

### Examples 2 to 5

In Examples 2 to 5, heat dissipation members were produced under the same condition as in Example 1 except that the silane coupling agent and the amount thereof added were changed to the condition shown in Table 1. 7-Octenyltrimethoxysilane has a vinyl group as the reactive organic group and an alkylene group having 6 carbon atoms as the organic chain connecting the reactive organic group and the Si atom. 3-Butenyltrimethoxysilane has a vinyl group as the reactive organic group and an alkylene group having 2 carbon atoms as the organic chain connecting the reactive organic group and the Si atom. 2-Propenyltrimethoxysilane has a vinyl group as the reactive organic group and an alkylene group having 1 carbon atom as the organic chain connecting the reactive organic group and the Si atom.

### Example 6

In Example 6, aggregated boron nitride particles were synthesized and a heat dissipation member was produced in the same manner as in Example 1 except that, in the decarbonization crystallization step, the amount of boric acid mixed with 100 parts by mass of boron carbonitride was changed from 90 parts by mass to 110 parts by mass.

### Example 7

In Example 7, aggregated boron nitride particles were synthesized in the same manner as in Example 1 except that in the decarbonization crystallization step, the temperature rise rate at 1,000° C. or more was changed from 2° C./min to 0.4° C./min, surface-treated aggregated boron nitride particles were produced and a heat dissipation member was produced in the same manner as in Example 1 except that the amount of the silane coupling agent added was changed from 1 part by mass to 0.7 part by mass per 100 parts by mass of the aggregated boron nitride particles.

### Example 8

In Example 8, aggregated boron nitride particles were synthesized and a heat dissipation member was produced in the same manner as in Example 1 except that, in the boron carbide synthesis step, the period of time of pulverization with a ball mill of the bulk boron carbide was changed from 1 hour to 20 minutes, and the sieving was changed from a particle diameter of 75 μm or less to 150 μm or less, so as to change the average particle diameter of the boron carbide powder from 20 μm to 48 μm.

### Comparative Example 1

Aggregated boron nitride particles were synthesized and a heat dissipation member was produced in the same manner as in Example 1 except that the surface treatment of the aggregated boron nitride particles with the silane coupling agent was not performed.

### Comparative Example 2

Aggregated boron nitride particles were synthesized and a heat dissipation member was produced in the same manner as in Example 1 except that, in the surface treatment of the aggregated boron nitride particles, a silane coupling agent having no spacer (trade name: KBM-1003, produced by Shin-Etsu Chemical Co., Ltd., compound name: vinyltrimethoxysilane) was used instead of the spacer type silane coupling agent. Vinyltrimethoxysilane has a vinyl group as the reactive organic group, and the reactive organic group and the Si atom are connected directly to each other. Accordingly, vinyltrimethoxysilane has no spacer as described above.

The evaluation results are shown in Tables 1 and 2 below.

TABLE 1

| | | | Example 1 | Example 2 | Example 3 | Example 4 | Example 5 |
|---|---|---|---|---|---|---|---|
| Hexagonal boron | Long diameter (r) | μm | 5 | 5 | 5 | 5 | 5 |
| nitride primary | Thickness (d) | μm | 0.4 | 0.4 | 0.4 | 0.4 | 0.4 |
| particles | Ratio (r/d) | — | 12.5 | 12.5 | 12.5 | 12.5 | 12.5 |
| Aggregated boron | Specific surface | m²/g | 4.0 | 4.0 | 4.0 | 4.0 | 4.0 |
| nitride particles | area | | | | | | |
| | Crushing strength | MPa | 9 | 9 | 9 | 9 | 9 |
| | Average particle | μm | 35 | 35 | 35 | 35 | 35 |
| | diameter | | | | | | |
| Silane coupling | Kind | — | 7-octenyl- | 7-octenyl- | 7-octenyl- | 3-butenyl- | 2-propenyl- |
| agent | | | trimethoxysilane | trimethoxysilane | trimethoxysilane | trimethoxysilane | trimethoxysilane |
| | Amount added per | part by | 1.0 | 0.2 | 1.4 | 1.0 | 1.0 |
| | 100 parts by mass | mass | | | | | |
| | of BN | | | | | | |
| Heat dissipation | Insulation breakdown | kV/mm | 58 | 53 | 50 | 56 | 50 |
| member | strength | | | | | | |
| | Relative thermal | — | 1.1 | 1.1 | 1.1 | 1.1 | 1.1 |
| | conductivity | | | | | | |
| | Voids | — | none | none | none | none | none |

TABLE 2

| | | | | | Comparative | Comparative |
|---|---|---|---|---|---|---|
| | | Example 6 | Example 7 | Example 8 | Example 1 | Example 2 |
| Hexagonal boron | Long diameter (r) | 8 | 5 | 5 | 5 | 5 |
| nitride primary | Thickness (d) | 0.6 | 0.7 | 0.4 | 0.4 | 0.4 |
| particles | Ratio (r/d) | 12.9 | 7.4 | 12.5 | 12.5 | 12.5 |
| Aggregated boron | Specific surface area | 2.2 | 3.8 | 4.0 | 4.0 | 4.0 |
| nitride particles | Crushing strength | 6 | 8 | 9 | 9 | 9 |
| | Average particle | 35 | 35 | 92 | 35 | 35 |
| | diameter | | | | | |
| Silane coupling | Kind | 7-octenyl- | 7-octenyl- | 7-octenyl- | — | Vinyl- |
| agent | | trimethoxysilane | trimethoxysilane | trimethoxysilane | | trimethoxysilane |
| | Amount added per 100 | 1.0 | 0.7 | 1.0 | — | 1.0 |
| | parts by mass of BN | | | | | |
| Heat dissipation | Insulation breakdown | 53 | 55 | 50 | 25 | 40 |
| member | strength | | | | | |
| | Relative thermal | 1.1 | 1.1 | 1.3 | 1.0 | 1.0 |
| | conductivity | | | | | |
| | Voids | none | none | none | found | found |

It was found from these evaluation results that the use of the aggregated boron nitride particles including the spacer type silane coupling agent suppressed the formation of voids in the heat dissipation member. It was found from the comparison of Examples 1, 4, and 5, with the same amount of the silane coupling agent added, that the use of the spacer type silane coupling agent having a longer spacer further improved the insulation breakdown characteristics of the heat dissipation member.

### INDUSTRIAL APPLICABILITY

The present invention particularly preferably relates to aggregated boron nitride particles excellent in thermal conductivity to be filled in a resin composition for an insulating layer of a printed circuit board and a thermal interface material, a method for producing the same, and a thermally conductive resin composition using the same.

The present invention specifically can be favorably applied to a raw material of a heat dissipation member for a heat generating electronic device, such as a power device.

The thermally conductive resin composition of the present invention can be widely applied to a heat dissipation member and the like.

1. Aggregated boron nitride particles comprising hexagonal boron nitride primary particles aggregated,
including a spacer type coupling agent.

2. The aggregated boron nitride particles according to claim 1, wherein the aggregated boron nitride particles have a content of the spacer type coupling agent of 0.1 to 1.5% by mass.

3. The aggregated boron nitride particles according to claim 1, wherein the spacer type coupling agent has at least one kind of a reactive organic group selected from the group consisting of an epoxy group, an amino group, a vinyl group, and a (meth)acryl group, a silicon atom bonded to at least one alkoxy group, and an alkylene group having 1 to 14 carbon atoms disposed between the reactive organic group and the silicon atom.

4. The aggregated boron nitride particles according to claim 3, wherein the reactive organic group of the spacer type coupling agent is a vinyl group.

5. The aggregated boron nitride particles according to claim 3, wherein the alkylene group has 6 to 8 carbon atoms.

6. The aggregated boron nitride particles according to claim 3, wherein the silicon atom bonded to an alkoxy group is trimethoxysilane.

7. A thermally conductive resin composition comprising the aggregated boron nitride particles according to claim 1.

8. A heat dissipation member comprising the thermally conductive resin composition according to claim 7.
